(19) United States
(12) Patent Application Publication
(10) Pub. No.: US 2023/0253359 A1
(43) Pub. Date: Aug. 10, 2023

(54) SEMICONDUCTOR DIE INCLUDING A METAL STACK

(71) Applicant: Wolfspeed, Inc., Durham, NC (US)

(72) Inventors: Alexander Komposch, Morgan Hill, CA (US); Arthur Fong-Yuen Pun, Raleigh, NC (US); Scott T. Sheppard, Chapel Hill, NC (US); Kevin Shawne Schneider, Cary, NC (US)

(21) Appl. No.: 17/665,191

(22) Filed: Feb. 4, 2022

(51) Int. Cl. H01L 23/00; H01L 29/20; H01L 29/16

(52) U.S. Cl. CPC H01L 24/29; H01L 29/2003; H01L 29/1608; H01L 29/7786

(57) ABSTRACT

A semiconductor die includes a silicon carbide (SiC) substrate and a metal stack. The SiC substrate has a first surface including a semiconductor layer thereon and a second surface that is opposite the first surface. The metal stack has an upper surface that attaches to the second surface of the SiC substrate and a lower surface that is opposite the upper surface. The metal stack includes a eutectic solder layer and a noble metal layer on the eutectic solder layer. The noble metal layer comprises a final metal layer on the lower surface.

### FIELD

The present disclosure relates to a semiconductor die, in particular a semiconductor die including a metal stack comprising a eutectic solder layer and a noble metal layer.

### BACKGROUND

Narrow bandgap semiconductor materials, such as silicon (Si) and gallium arsenide (GaAs), are widely used in semiconductor devices for low power and, in the case of Si, low frequency applications. However, these semiconductor materials may not be well-suited for high power and/or high frequency applications, for example, due to their relatively small bandgaps (1.12 eV for Si and 1.42 for GaAs at room temperature) and relatively small breakdown voltages.

Interest in high power, high temperature and/or high frequency applications and devices has focused on wide bandgap semiconductor materials such as silicon carbide (3.2 eV for 4H-SiC at room temperature) and the Group III nitrides (e.g., 3.36 eV for GaN at room temperature). These materials may have higher electric field breakdown strengths and higher electron saturation velocities than GaAs and Si.

A device of particular interest for high power and/or high frequency applications is the High Electron Mobility Transistor (HEMT), which is also known as a modulation doped field effect transistor (MODFET). In a HEMT device, a two-dimensional electron gas (2DEG) may be formed at the heterojunction of two semiconductor materials with different bandgap energies, where the smaller bandgap material has a higher electron affinity than the wider bandgap material. The 2DEG is an accumulation layer in the undoped smaller bandgap material and can contain a relatively high sheet electron concentration, for example, in excess of 1013 carriers/cm². Additionally, electrons that originate in the wider bandgap semiconductor may transfer to the 2DEG, allowing a relatively high electron mobility due to reduced ionized impurity scattering. This combination of relatively high carrier concentration and carrier mobility can give the HEMT a relatively large transconductance and may provide a performance advantage over metal-semiconductor field effect transistors (MESFETS) for high-frequency applications.

HEMTs fabricated in the gallium nitride/aluminum gallium nitride (GaN/AlGaN) material system can generate large amounts of RF power due to a combination of material characteristics, such as relatively high breakdown fields, relatively wide bandgaps, relatively large conduction band offset, and/or relatively high saturated electron drift velocity. A major portion of the electrons in the 2DEG may be attributed to polarization in the AlGaN.

Semiconductor die, in particular, power semiconductor die, are often mounted on a package. A semiconductor die structure may have a metal backside, including a metal outer layer. The backside may be used to attach the semiconductor die to the package (referred to herein as die attach). A connection between the semiconductor die and the package is produced by, e.g., attaching the semiconductor die via sintering/gluing or a solder connection. The connection between the semiconductor die and the package can be produced by the formation of intermetallic compounds at the boundary between the metal of the semiconductor die and the surface of the package.

Semiconductor die structures may have a backside that is compatible with select types of die attach and is incompatible with other types of die attach, which can contribute to high manufacturing costs and manufacturing and inventory inefficiencies due to semiconductor die having different backsides and limited die attach compatibility, and/or other limitations for die attach to a package.

### SUMMARY

A semiconductor die according to some embodiments includes a silicon carbide (SiC) substrate having a first surface including a semiconductor layer thereon and a second surface that is opposite the first surface. The semiconductor die further includes a metal stack having an upper surface that attaches to the second surface of the SiC substrate and a lower surface that is opposite the upper surface. The metal stack includes a eutectic solder layer and a noble metal layer on the eutectic solder layer. The noble metal layer includes a final metal layer on the lower surface.

The eutectic solder layer may be a eutectic or a near eutectic material.

The final metal layer may be gold (Au) or silver (Ag).

The final metal layer may be configured to be compatible with any one of a eutectic solder material, a sintering material, and a glue material for attachment of the semiconductor die to a package.

In some embodiments, the eutectic solder layer includes at least one of (i) gold (Au) and tin (Sn) having a respective ratio by weight percent of about 80/20, (ii) copper (Cu) and Sn having a respective ratio by weight percent of about 6/94, (iii) silver (Ag) and Sn having a respective ratio by weight percent of about 10/90, and (iv) Au and germanium (Ge) having a respective ratio by weight percent of about 20/80.

The eutectic solder layer may include at least one of (i) Au and Sn having a respective ratio by weight percent of about 75/25, (ii) copper (Cu) and Sn having a respective ratio by weight percent of about 4/96, (iii) silver (Ag) and Sn having a respective ratio by weight percent of about 8/92, and (iv) Au and germanium (Ge) having a respective ratio by weight percent of about 17/83.

The eutectic solder layer may include at least one of (i) Au and Sn having a respective ratio by weight percent of about 70/30, (ii) copper (Cu) and Sn having a respective ratio by weight percent of about 2/98, (iii) silver (Ag) and Sn having a respective ratio by weight percent of about 5/95, and (iv) Au and germanium (Ge) having a respective ratio by weight percent of about 14/86.

The eutectic solder layer may include at least one of (i) Au and Sn having a respective ratio by weight percent of about 65/35, (ii) copper (Cu) and Sn having a respective ratio by weight percent of about 0/100, (iii) silver (Ag) and Sn having a respective ratio by weight percent of about 0/100, and (iv) Au and germanium (Ge) having a respective ratio by weight percent of about 10/90.

In some embodiments, the final metal layer has a thickness of about 500 nm.

In some embodiments, the final metal layer has a thickness in a range between about 50 and less than about 500 nm.

In some embodiments, the final metal layer has a thickness in a range between about 500 nm to about 1000 nm.

In some embodiments, the eutectic solder layer has a thickness of about 3600 nm.

In some embodiments, the final metal layer is configured to diffuse into the eutectic solder layer during at least a partial phase transition of the eutectic solder layer from a solid to a liquid state that happens during a die attach that allows the attachment of the semiconductor die to a surface of a package comprising at least one of Au, Ag, or Cu.

In some embodiments, the eutectic solder layer is configured to go through the at least partial phase transition from the solid to the liquid state at a temperature range of about 200° C. to about 450° C.

In some embodiments, the eutectic solder layer includes a combination of Au and Sn in a ratio by weight percent of Au/Sn in a range of about 65/35 to about 80/20, and the eutectic solder layer is configured to have the at least partial phase transition to the liquid state at a temperature of about 278° C.

In some embodiments, the final metal layer is configured to stay intact during a die attach at a temperature below a eutectic melting point of the eutectic solder layer that allows attachment of the semiconductor die with a Ag sintering material or a glue material to a surface of a package comprising at least one of Au, Ag, and Cu.

In some embodiments, the eutectic solder layer is configured to not go through a phase transition to a liquid state at a temperature range of about 100° C. to lower than the eutectic melting point of the eutectic solder layer.

In some embodiments, the final metal layer is configured to allow attachment of the semiconductor die with at least one of a Ag, a Au, and a Cu sintering material or at least one of a conductive or a non-conductive the glue material at a temperature of about 200° C.

The semiconductor layer may include a group III nitride layer.

The semiconductor layer may include a SiC layer.

The semiconductor die may include a HEMT die and the semiconductor layer may include a gallium nitride (GaN) layer.

The semiconductor die may include a metal-oxide-semiconductor field effect transistor (MOSFET) die and the semiconductor layer may include a SiC layer.

The semiconductor die may include at least one via extending through the SiC substrate from the second surface thereof toward the first surface thereof, and the metal stack may conformally extend along the second surface of the SiC substrate and within the via along sidewall surfaces thereof such that the via is unfilled.

The semiconductor die may be a RF transistor formed as part of a monolithic microwave integrated circuit (MMIC), and the MMIC may include vias connected to a circuit element of the RF transistor.

A semiconductor die according to some embodiments includes a SiC substrate having a first surface including a semiconductor layer thereon and a second surface that is opposite the first surface. The semiconductor die further includes a metal stack having an upper surface that attaches to the second surface of the SiC substrate and a lower surface that is opposite the upper surface. The metal stack includes a final metal layer including Au on the lower surface, a eutectic solder layer on the final metal layer, a barrier layer on the eutectic solder layer, and a metal interlayer including nickel between the eutectic solder layer and the barrier layer.

In some embodiments, the final metal layer is configured to be compatible with any one of a eutectic solder material, a sintering material, and a glue material during attachment of the die to a package.

In some embodiments, the eutectic solder layer includes Au and Sn having a ratio by weight percent of Au/Sn in a range between about 65/35 and about 80/20.

The sintering material may include at least one of Ag, Au, and Cu.

In some embodiments, the metal interlayer and the final metal layer are configured to diffuse into the eutectic solder layer during at least a partial phase transition of the eutectic solder layer from a solid to a liquid state that happens during a die attach that allows the attachment of the semiconductor die to a surface of a package comprising at least one of Au, Ag, or Cu.

In some embodiments, the metal interlayer and the final metal layer are configured to stay intact, during die attach at a temperature below a eutectic melting point of the eutectic solder layer that allows attachment of the semiconductor die with a Ag sintering material or a glue material to a surface of a package comprising at least one of Au, Ag, and Cu.

The semiconductor layer may include a SiC layer.

The semiconductor die may include a HEMT die and the semiconductor layer may include a GaN layer.

The semiconductor die may include a MOSFET die and the semiconductor layer may include a SiC layer.

The semiconductor die may include at least one via extending through the SiC substrate from the second surface thereof toward the first surface thereof, and the metal stack may conformally extend along the second surface of the SiC substrate and within the via along sidewall surfaces thereof such that the via is unfilled.

The semiconductor die may be a RF transistor formed as part of a MMIC, and the MMIC may include vias connected to a circuit element of the RF transistor.

### BRIEF DESCRIPTION OF THE DRAWINGS

FIG. 1 is a schematic cross-sectional view of a semiconductor die including a metal stack according to some embodiments of the present disclosure.

FIG. 2 is a schematic cross-sectional view of a semiconductor die and a package, the semiconductor die including a metal stack according to some embodiments.

FIG. 3 is a schematic cross-sectional view of a semiconductor die and a package, the semiconductor die including a metal stack according to some embodiments.

FIG. 4 is a plot illustrating a phase diagram for example embodiments.

FIG. 5 is a schematic cross-sectional view of a semiconductor structure including a semiconductor die according to some embodiments of the present disclosure, and FIG. 5A1 is an enlarged view of a portion of FIG. 5.

FIG. 6 is a schematic cross-sectional view of a semiconductor device including a semiconductor die during die attach to a package according to some embodiments of the present disclosure, and FIG. 6A1 is an enlarged view of a portion of FIG. 6.

FIG. 7A is a schematic cross-sectional view of a HEMT cell structure on a semiconductor die in accordance with some embodiments of the present disclosure.

FIG. 7B is a schematic cross-sectional view of a laterally diffused metal oxide semiconductor (LDMOS) transistor device cell structure on a semiconductor die in accordance with some embodiments of the present disclosure.

FIGS. 8A-8C are schematic block diagrams of multi-amplifier circuits in which RF transistor amplifiers incorporating semiconductor die according to embodiments may be used.

FIG. 9 is a schematic illustration of a MMIC amplifier including a HEMT transistor according to some embodiments.

FIGS. 10A and 10B are schematic cross-sectional views illustrating example packages for RF transistor amplifier semiconductor dies according to some embodiments.

### DETAILED DESCRIPTION OF EMBODIMENTS

Embodiments of the inventive concepts will now be described in connection with the accompanying drawings. Some embodiments described herein provide a semiconductor die including a SiC substrate having a first surface including a semiconductor layer thereon and a second surface that is opposite the first surface. The semiconductor die further includes a metal stack having an upper surface that attaches to the second surface of the SiC substrate and a lower surface that is opposite the upper surface. The metal stack includes a eutectic solder layer and a noble metal layer on the eutectic solder layer. The noble metal layer comprises a final metal layer on the lower surface.

It is understood that, although the ordinal terms first, second, third, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

Furthermore, relative terms, such as “lower” or “bottom” and “upper” or “top,” may be used herein to describe the relationship of one element to another as illustrated in the drawings. It is understood that relative terms are intended to encompass different orientations of the device in addition to the orientation depicted in the drawings. For example, if the device in one of the drawings is turned over, features described as being on the “lower” side of an element would then be oriented on “upper” side of that element. The exemplary term “lower” can therefore describe both lower and upper orientations, depending on the particular orientation of the device. Similarly, if the device in one of the drawings is turned over, elements described as “below” or “beneath” other elements would then be oriented above those other elements. The exemplary terms “below” or “beneath” can therefore describe both an orientation of above and below.

The terminology used in the description of the disclosure herein is for the purpose of describing particular embodiments only and is not intended to be limiting of the disclosure. As used in the description of the disclosure and the appended claims, the singular forms “an” and “the” are intended to include the plural forms as well, unless the context clearly indicates otherwise. It is also understood that the term “and/or” as used herein refers to and encompasses any and all possible combinations of one or more of the associated listed items. It will be further understood that the terms “comprises” and “comprising,” when used in this specification, specify the presence of stated steps, operations, features, elements, and/or components, but do not preclude the presence or addition of one or more other steps, operations, features, elements, components, and/or groups thereof.

Embodiments of the disclosure are described herein with reference to cross-sectional view illustrations that are schematic illustrations of idealized embodiments of the disclosure. As such, variations from the shapes of the illustrations as a result, for example, of manufacturing techniques and/or tolerances, are to be expected. Thus, embodiments of the disclosure should not be construed as limited to the particular shapes or thicknesses of regions illustrated herein but are to include deviations in shapes and thicknesses that result, for example, from manufacturing. The regions illustrated in the drawings are schematic in nature, and their shapes and thicknesses are not intended to illustrate the actual shape or thickness of a region of a semiconductor die and are not intended to limit the scope of the disclosure unless explicitly stated otherwise. Further, lines that appear straight, horizontal, or vertical in the below drawings for schematic reasons will often be sloped, curved, non-horizontal, or non-vertical.

Unless otherwise defined, all terms used in disclosing embodiments of the disclosure, including technical and scientific terms, have the same meaning as commonly understood by one of ordinary skill in the pertinent art and are not necessarily limited to the specific definitions known at the time of the present disclosure. Accordingly, these terms can include equivalent terms that are created after such time. It is further understood that terms, such as those defined in commonly used dictionaries, should be interpreted as having a meaning that is consistent with their meaning in the present specification and in the context of the relevant art.

Die attach may refer to operations that result in electrical and thermal connection between a semiconductor layer on a substrate (collectively referred to as a semiconductor die) and a package or packaging substrate (which may be a different material than the semiconductor die). A semiconductor wafer typically includes a substrate (e.g., a silicon carbide (SiC) substrate) having a first surface including a semiconductor layer thereon and a second surface that is opposite the first surface. A metal stack having an upper surface is attached to the second surface of the substrate. The metal stack has a lower surface that is opposite the upper surface. The metal stack includes a final metal layer on the lower surface of the metal stack. The term “lower surface” herein may be interchangeable and replaced with the term “backside”.

Die attach operations typically occur after the dicing or sawing of a semiconductor wafer into individual semiconductor die including the metal stack on the second surface of the substrate. Some die attach operations may involve the attachment of the semiconductor die to a metal die attach region or flange of a package by way of a solder-based die attach (also referred to herein as a eutectic die attach). During solder-based die attach, the lower surface of the metal stack of the semiconductor die and the die attach region of the package typically are placed together, and are subjected to temperatures that are sufficiently high (e.g., greater than about 230° C. depending on the die attach material, as discussed further herein) to effect reflow of a die attach material, that is, a phase transition of the die attach material from a solid phase to a liquid phase. The die attach material may be a metal layer (e.g., a metal layer comprising AuSn) on the lower surface of the metal stack or a metal preform (e.g., a AuSn preform attached to the metal stack and forming a lower surface of the metal stack).

Other die attach operations may involve the attachment of the semiconductor die to a metal die attach region or flange of the package by way of a sintering or glue attach material. During sintering/gluing-based die attach, the sintering or glue material may be deposited on a surface of the package or die backside of the die. The semiconductor die (e.g., the lower surface of the metal stack) and the surface of the package including the sintering or glue material are placed together, and are subjected to sintering/curing temperatures (e.g., less than about 270° C.) to enable the sintering process or the curing process of the glue material.

Some embodiments may arise from realization that, in die attach operations for semiconductor die having a final metal layer comprising gold-tin (AuSn) on the lower surface of the metal stack, sintering/gluing-based die attach (e.g., sintering using Ag, Au, or Cu sintering) may not work to attach the semiconductor die to a surface of a package (e.g., a surface of the package comprising Au, Ag, or Cu). For example, with Ag, Au, or Cu nano sintering materials, the Sn may not sinter or, if it does, the interface between the semiconductor die and the surface of the package may not be stable nor reliable.

Further, some embodiments may arise from the realization that, in solder-based die attach operations, a AuSn preform may need to be added to a semiconductor die having a Au layer on the lower surface of the semiconductor die in order to attach the semiconductor die to the package (e.g., a surface of the package comprising Au, Ag, or Cu). Attaching the AuSn preform to the semiconductor die, however, may cause inefficiencies in the die attach process (e.g., slowing down the process), increase costs (e.g., based on addition of the AuSn preform), and decreased yield (e.g., based on an increased amount of surfaces to be created during die attach which may have a higher probability of encountering voids in the solder).

Thus, two different die attach operations may be used for semiconductor die having different backside structures, e.g., semiconductor die having a Au backside and semiconductor die having a AuSn backside. Different die attach operations based on the different semiconductor die backsides may cause inefficiencies, increased costs, and inventory logistics issues related to die attach processes based on a need to have certain semiconductor die structures in inventory for different die attach operations.

Some embodiments provide a universal backside of a semiconductor die that includes a metal stack having a eutectic solder layer and a noble metal layer as the final metal layer on the backside of the semiconductor die. Such a eutectic solder layer and a noble metal layer provide material that can work for both sintering/gluing (e.g., Ag, Au, or Cu sintering/gluing) and for soldering (e.g., AuSn eutectic solder material) based die attach. As a consequence, die attach operations may be simplified, less expensive, and more efficient as a result of the universal backside. Moreover, the universal backside may be used for all, or for a significant variety, of power products (e.g., radio frequency (RF) power products). Thus, a structure of semiconductor die for a power product portfolio may be simplified, and efficiency, cost, and inventory logistics of die supply and die attach operations may be improved for an RF power product portfolio based on semiconductor die including a universal backside.

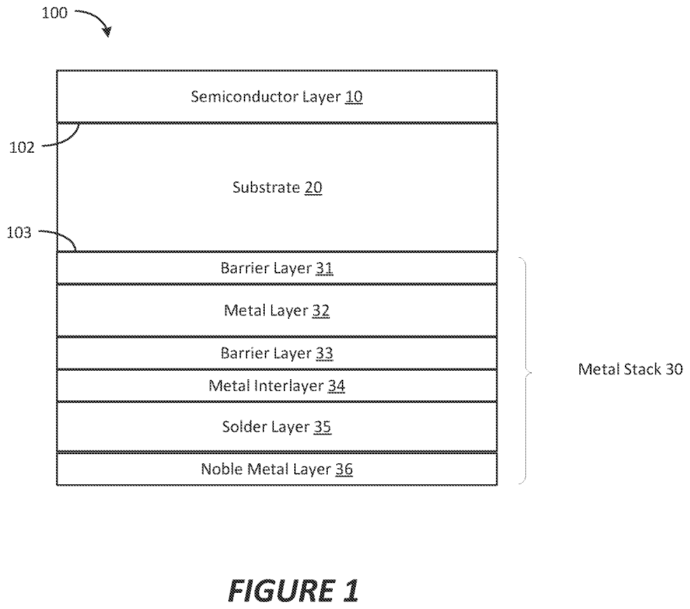

A semiconductor die 100 structure according to some embodiments is illustrated in FIG. 1. As shown therein, the structure includes a semiconductor layer 10 on a first surface 102 (also referred to as a frontside) of a substrate layer 20 (also referred to herein as a substrate). The semiconductor layer 10 may include wide-bandgap semiconductor materials, such as SiC and/or Group III nitride-based materials, which may be formed as one or more epitaxial layers on the substrate layer 20, described primarily herein with reference to SiC substrates by way of example. The use of a substrate and epitaxial layer(s), which in some embodiments may be the same material, may result in improved crystal lattice in the epitaxial layers as compared to the substrate. In some embodiments, the semiconductor layer 10 may include one or more layers of semiconductor material other than SiC (such as Group III nitride-based layers) formed on a SiC or other substrate. The Group III nitride layers may define the channel regions of transistor devices in the semiconductor layer 10, for example, FETs or HEMTs.

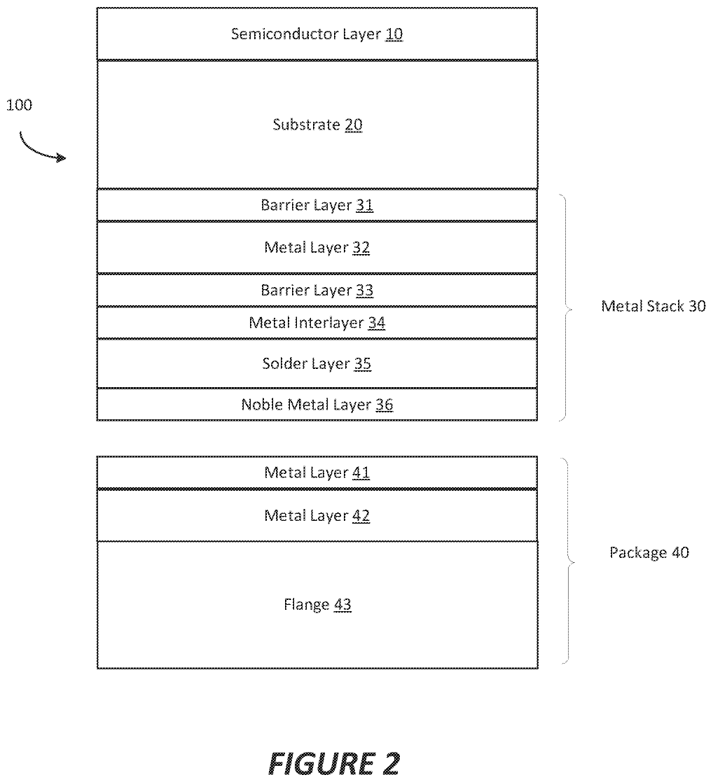

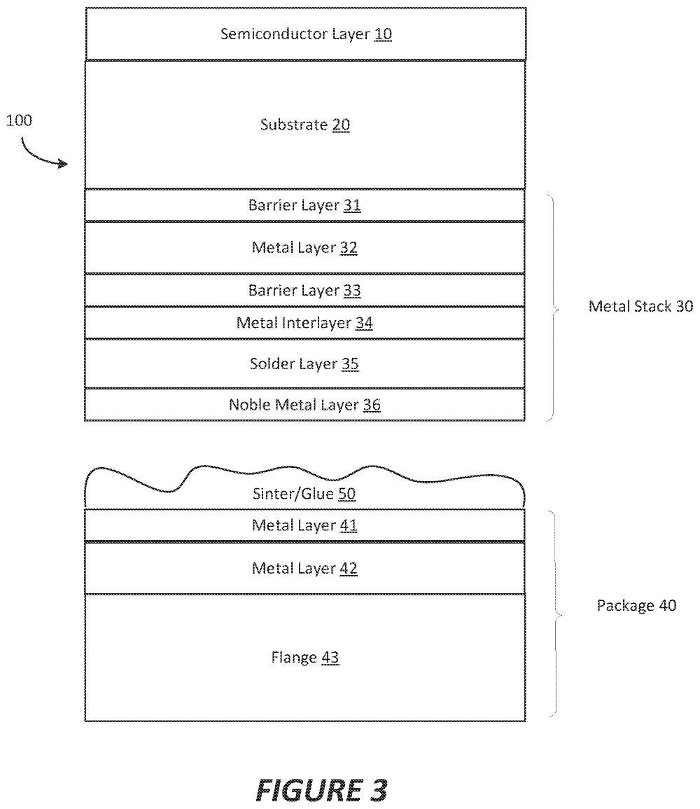

The semiconductor die 100 further includes a metal stack 30 on a second surface 103 (also referred to herein as the “backside”) of the substrate 20. The metal stack 30 includes one or more layers 34, 35, and 36 of the same or different metals or metal alloys that are selected and formed to provide improved performance, yield, and/or reliability of the attachment of the semiconductor die 100 to a surface of a package (such as the metal layer 41 of package 40 shown in in FIGS. 2 and 3).

The eutectic solder layer 35 may include one or more materials, alloys, and/or layers comprising a eutectic or a near eutectic material. For example, the eutectic solder layer 35 may include a eutectic or near eutectic mixture of a desired metal alloy, such as AuSn, CuSn, AgSn, AuGe, etc., in all-eutectic, over-eutectic, or under-eutectic compositions. As referred to herein, a near eutectic material may refer to up to about 25% over- or under-eutectic compositions. Eutectic AuSn may include about 80% Au and about 20% Sn. Near eutectic AuSn as described herein may range from about 65% Au and 35% Sn, to about 75% Au and 25% Sn. For example, a AuSn eutectic solder layer 35 may include about 70% Au and about 30% Sn, including relative concentrations that may vary while remaining sufficiently near eutectic to maintain a suitable melting point. The eutectic solder layer 35 can be deposited (e.g., plated, evaporated, sputtered) as a single or multiple layers. In some embodiments, the eutectic solder layer 35 may include multiple layers that are separated by respective, thinner layers. For example, a AuSn eutectic solder layer 35 may include multiple AuSn or Au and Sn layers separated by respective thin Au layers, which may achieve a smoother surface finish. In other embodiments, the eutectic solder layer 35 may be a single layer sputtered all at once.

In some embodiments, eutectic solder layer 35 may be a solderable metal (e.g., near eutectic AuSn) having a thickness of about 3600 nm.

In various embodiments, noble metal layer 36 is a final metal layer on the lower surface of the metal stack 30. In some embodiments, noble metal layer 36 may include one or more materials and/or layers configured to be compatible with any one of a eutectic solder material, a sintering material, and a glue material for attachment of the semiconductor die 100 to a package. As a consequence, noble metal layer 36 may provide a surface that allows either a solder-based die attach operation or a gluing/sintering-based die attach operation to a surface of a package.

For example, referring to FIG. 2, in some embodiments, the noble metal layer 36 is configured to diffuse (e.g., dissolve or melt) into the eutectic solder layer 35 during at least a partial phase transition of the eutectic solder layer 35 from a solid to a liquid state that happens during a die attach that allows the attachment of the semiconductor die 100 to a surface of a package including at least one of gold (Au), silver (Ag), or copper (Cu). In some embodiments, the eutectic solder layer 35 is configured to go through the at least partial phase transition from solid to the liquid state at a temperature range of about 200° C. to about 450° C.

In some embodiments, the eutectic solder layer 35 comprises a combination of gold (Au) and tin (Sn) in a ratio by weight percent of Au/Sn in a range of about 65/35 to about 80/20, and the eutectic solder layer 35 is configured to have the at least partial phase transition to the liquid state at a temperature of about 278° C.

In some embodiments, the eutectic solder layer 35 comprises a combination of copper (Cu) and tin (Sn) in a ratio by weight percent of Cu/Sn in a range of about 6/94 to about 0/100, and the eutectic solder layer 35 is configured to have the at least partial phase transition to the liquid state at a temperature of about 230° C.

In some embodiments, the eutectic solder layer 35 comprises a combination of silver (Ag) and tin (Sn) in a ratio by weight percent of Ag/Sn in a range of about 10/90 to about 0/100, and the eutectic solder layer 35 is configured to have the at least partial phase transition to the liquid state at a temperature of about 230° C.

In some embodiments, the eutectic solder layer 35 comprises a combination of gold (Au) and germanium (Ge) in a ratio by weight percent of Au/Ge in a range of about 10/80 to about 10/90, and the eutectic solder layer 35 is configured to have the at least partial phase transition to the liquid state at a temperature of about 360° C.

Referring to FIG. 3, in other example embodiments, with reference to gluing/sintering-based die attach, the eutectic solder layer 35 also is configured to not go through a phase transition to a liquid state at a temperature range of about 100° C. to 270° C. In some embodiments, the final metal layer (e.g., noble metal layer 36) is configured to stay intact during a die attach at a temperature below a eutectic melting point of the eutectic solder layer 35 that allows attachment of the semiconductor die 100 with a sintering or glue material 50 (e.g., Ag sintering material) at a sintering/curing temperature of about 200° C.

In some embodiments, the noble metal layer 36 may include gold (Au) or silver (Ag), for example, having thickness of about 50 nm to about 500 nm, e.g., a thickness of about 500 nm. In some embodiments, the noble metal layer 36 may include gold (Au) or silver (Ag), for example, having thickness of about 500 nm to about 1000 nm.

This backside metal stack 30 may include one or more layers 31, 32 of the same or different metals or metal alloys that are selected and formed to provide improved device performance. In some embodiments, the barrier layer 31 may include titanium tungsten (TiW) or alternating layers of TiW and platinum (Pt). More generally, possible barrier layer materials may include Ti, TiW, Pt, Cr, including multiple and/or alternating layers thereof. The metal layer 32 may include one or more materials, alloys, and/or layers configured to provide desired device performance characteristics, such as low electrical resistance and high electrical current capacity or carrying capability. In some embodiments, the metal layer 32 may include Au having a thickness of between about 1 micron (μm) to about 15 μm. For example, the metal stack 30 may include a 0.5 μm (+0.25 μm) TiW barrier layer 31, and a 6 μm (12 μm) Au metal layer 32 on a backside surface of a SiC substrate 20. The barrier layer 33 may include one or more materials, alloys, and/or layers configured to prevent migration of the material(s) of the eutectic solder layer 35 and/or the noble metal layer 36 into the metal layer 32. In some embodiments, the barrier layer 33 may include platinum (Pt) and/or tungsten (W), for example, having thickness of about 0.1 μm to about 1 μm, e.g., 0.1 μm to 0.5 μm. The various layers of the stacks described herein may be continuous or discontinuous in some embodiments.

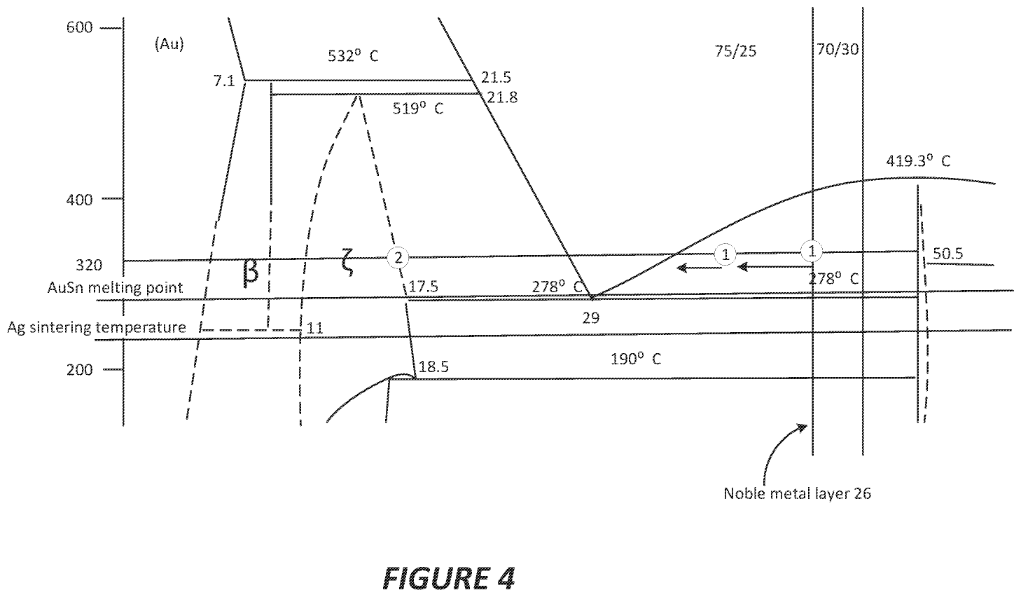

FIG. 4 is plot illustrating a phase diagram for example embodiments that include a AuSn eutectic solder layer 35 having a weight percentage of Au/Sn in a range of about 70/30 to about 75/25, and a thickness of about 3600 nm; and a Au noble metal layer 36 having a thickness of about 500 nm.

As shown in the example embodiments of FIG. 4, for a solder-based die attach operation when the metal stack 30 includes a AuSn eutectic solder layer 35, the melting point of a AuSn eutectic solder layer 35 having a weight percentage of Au/Sn of about 70/30 is about 278° C.; and the melting point of a AuSn eutectic solder layer 35 having a weight percentage of Au/Sn of about 75/25 is about 320° C. Further, for a sintering-based die attach operation, a Ag sintering temperature is about 240° C.

As a consequence, during a solder-based die attach operation of a AuSn eutectic solder layer 35 having a weight percentage of Au/Sn in a range between about 70/30 to about 75/25, the Au noble metal layer 36 is configured to diffuse into the eutectic solder layer 35 during at least a partial phase transition of the eutectic solder layer 35 from a solid to a liquid state that happens during the die attach that allows the attachment of the semiconductor die 100 to a surface of package (e.g., which may result in a stable bond with a surface of the package (e.g., a Au metal layer 41 of package 40)).

In contrast, during a Ag sintering/gluing-based die attach operation, such a AuSn eutectic solder layer 35 also is configured to not go through a phase transition to a liquid state at the Ag sintering/gluing temperature of about 240° C., and the Au final metal layer 36 can stay intact when the semiconductor die 100 is attached to a surface of a package (e.g., to metal layer 41 of package 40).

A Ag sintering and gluing temperature is in a range of about 100° C. to 270° C.; while a temperature for soldering-based die attach for a AuSn eutectic solder layer 35 can be in a range between about 278° C. and 320° C. At Ag sintering/gluing temperatures, a Au final metal layer 36 may remain intact during and after die attach; while at solder-based die attach temperatures, the Au noble metal layer 36 is configured to diffuse into the eutectic solder layer 35 during at least a partial phase transition of the eutectic solder layer 35 from a solid to a liquid state that allows the attachment of the semiconductor die 100 to a surface of a package. Thus, the structure of the semiconductor die 100 may be compatible with both sintering/gluing-based die attach and solder-based die attach.

A AuSn eutectic solder layer 35 and a Au noble metal layer 36 are included as examples for possible configurations of a semiconductor die, but it will be understood that other materials for the eutectic solder layer 35 and the noble metal layer 36 could be utilized in semiconductor dies as described herein without deviating from the scope of embodiments of the present disclosure. As such, the present invention is not limited to semiconductor die including a AuSn eutectic solder layer 35 and a Au noble metal layer 36.

In some embodiments, the eutectic solder layer 35 comprises at least one of (i) gold (Au) and tin (Sn) having a respective ratio by weight percent of about 80/20 to about 65/35, (ii) copper (Cu) and Sn having a respective ratio by weight percent of about 6/94 to about 0/100, (iii) silver (Ag) and Sn having a respective ratio by weight percent of about 10/90 to about 0/100, and (v) Au and germanium (Ge) having a respective ratio by weight percent of about 20/80 to about 10/90.

In some embodiments, eutectic solder layer 35 may include at least one of (i) gold (Au) and tin (Sn) having a respective ratio by weight percent of about 80/20, (ii) copper (Cu) and Sn having a respective ratio by weight percent of about 6/94, (iii) silver (Ag) and Sn having a respective ratio by weight percent of about 10/90, and (iv) Au and germanium (Ge) having a respective ratio by weight percent of about 20/80.

In some embodiments, eutectic solder layer 35 may include at least one of (i) gold (Au) and tin (Sn) having a respective ratio by weight percent of about 75/25, (ii) copper (Cu) and Sn having a respective ratio by weight percent of about 4/96, (iii) silver (Ag) and Sn having a respective ratio by weight percent of about 8/92, and (iv) Au and germanium (Ge) having a respective ratio by weight percent of about 17/83.

In some embodiments, eutectic solder layer 35 may include at least one of (i) gold (Au) and tin (Sn) having a respective ratio by weight percent of about 70/30, (ii) copper (Cu) and Sn having a respective ratio by weight percent of about 2/98, (iii) silver (Ag) and Sn having a respective ratio by weight percent of about 5/95, and (iv) Au and germanium (Ge) having a respective ratio by weight percent of about 14/86.

In some embodiments, eutectic solder layer 35 may include at least one of (i) gold (Au) and tin (Sn) having a respective ratio by weight percent of about 65/35, (ii) copper (Cu) and Sn having a respective ratio by weight percent of about 0/100, (iii) silver (Ag) and Sn having a respective ratio by weight percent of about 0/100, and (iv) Au and germanium (Ge) having a respective ratio by weight percent of about 10/90.

Referring again to the example embodiments of FIG. 4, during a solder-based die attach, a Au final metal layer 36 may decrease the relative amount of Sn in the final AuSn material due to diffusion of Au from the Au final metal layer 36 into the liquid sate of the Au/Sn eutectic solder layer 35. As a consequence, the final AuSn eutectic solder material of the final solder joint may become brittle, as illustrated by the circle numbered “2” on FIG. 4. Thus, while a Au final metal layer 36 is not needed for a solder-based die attach and may result in an unstable final solder joint, and not wishing to be bound by a particular theory, it is presently believed that increasing the weight percentage of Sn in the AuSn eutectic solder layer 35 (e.g., a weight percentage of Sn in a range from about 20% to about 35%) may move the final AuSn eutectic solder material further away from being a eutectic mixture, as shown by the circles numbered “1” in FIG. 4. As a consequence, a stable final solder joint may be obtained. Thus, while a Au final metal layer 36 is not needed for a solder-based die attach, inclusion of a Au final metal layer 36 and a AuSn eutectic solder layer 35 having a respective ratio by weight percent of about 65/35 to about 80/20 may allow the semiconductor die 100 to be compatible with both solder-based die attach and with sintering/gluing-based die attach.

Referring again to FIG. 1, some embodiments may include a metal interlayer 34 comprising nickel (Ni) between the barrier layer 33 and the eutectic solder layer 35. The metal interlayer 34 may include Ni configured to alloy with and/or otherwise interact with the eutectic solder layer 35 so as to prevent contact between the liquid phase of the eutectic solder layer 35 and the barrier layer 33.

In some embodiments, the metal interlayer 34 and the final metal layer 36 are configured to diffuse into the eutectic solder layer 35 during at least a partial phase transition of the eutectic solder layer 35 that happens during the die attach that allows the attachment of the semiconductor die 100 to a surface of a package comprising at least one of Au, silver (Ag), or copper (Cu).

In some embodiments, the metal interlayer and the final metal layer are configured to stay intact during sintering or glue-based die attach at a temperature below a eutectic melting point of the eutectic solder layer 35 that allows attachment of the semiconductor die 100 with a silver (Ag), a gold (Au), or a copper (Cu) sintering material (e.g., a nano Ag sintering material) or a glue material to a surface of a package comprising at least one of Au, Ag, and Cu.

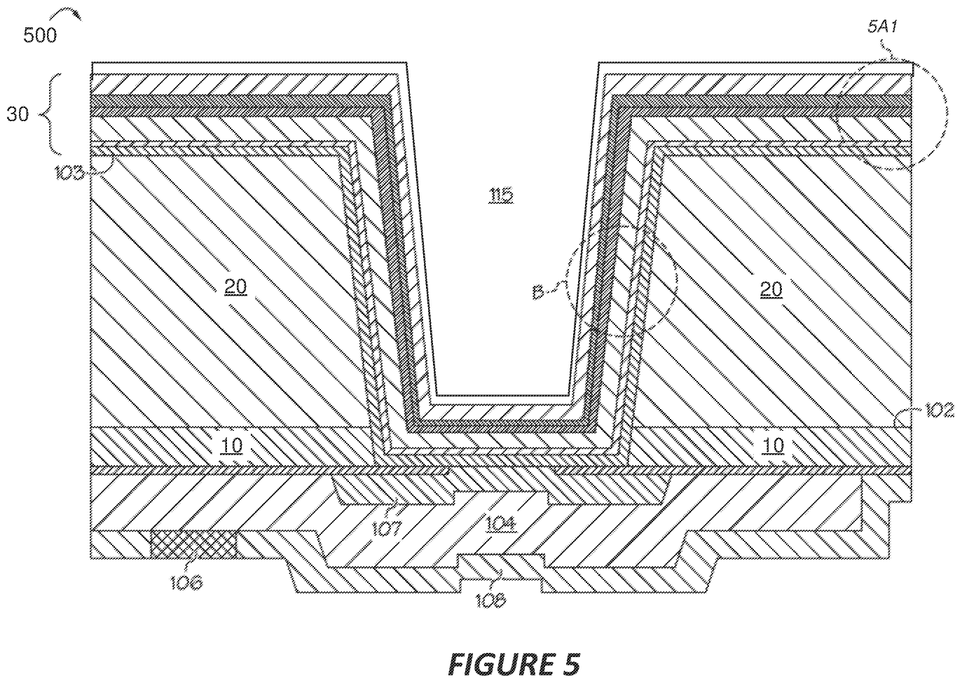

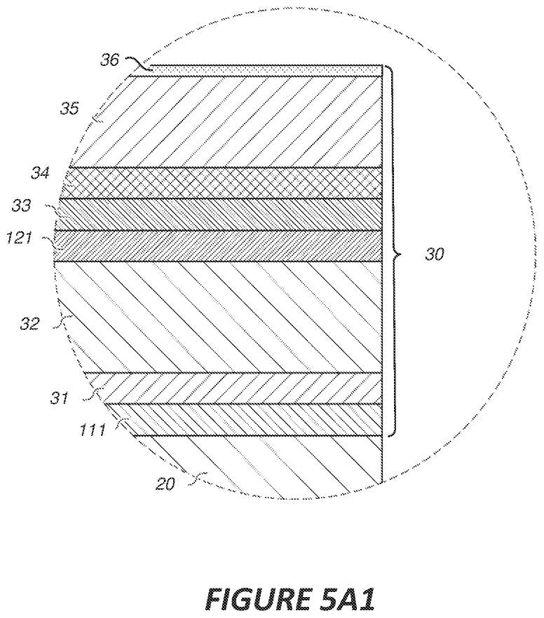

FIG. 5 is a schematic cross-sectional view of a semiconductor structure 500 that includes a semiconductor die 100 in accordance with some embodiments. FIG. 5A1 is an enlarged view of a portion of FIG. 5 of the semiconductor die of the present disclosure. As shown in FIG. 5, a semiconductor structure 500 includes a semiconductor layer 10 on a first surface 102 of a substrate 20. The semiconductor layer 10 may include wide-bandgap semiconductor materials, such as SiC and/or Group III nitride-based materials, which may be formed as one or more epitaxial layers on the substrate 20, described primarily herein with reference to SiC substrates by way of example. The use of a substrate and epitaxial layer(s), which in some embodiments may be the same material, may result in improved crystal lattice in the epitaxial layers as compared to the substrate. In some embodiments, the semiconductor layer 10 may include one or more layers of semiconductor material other than SiC (such as Group III nitride-based layers) formed on a SiC or other substrate. The Group III nitride layers may define the channel regions of transistor devices in the semiconductor layer 10, for example, field effect transistors (FETs) or high electron mobility transistors (HEMTs).

The semiconductor structure 500 further includes a metal stack 30 on the second surface 103 of the substrate 20. The metal stack 30 includes at least one or more of the layers 31, 32, 33, 34, 35, and 36 described herein with reference to FIGS. 1-3 configured to provide improved performance, yield, and/or reliability of the attachment of a semiconductor die 100 to a surface of a package. Metal stack 30 may further include one or more adhesion layers 111, 121. The adhesion layers 111, 121 may include one or more materials, alloys, and/or layers configured to promote adhesion with the second surface 103 of substrate 20 and with a surface of the metal layer 32, respectively. In some embodiments, the adhesion layers 111, 121 may include titanium (Ti).

Still referring to FIG. 5, the metal stack 30 includes portions on the second surface 103 as well as around the periphery of and within a through substrate via 115 that extends from the second surface 103 to the first surface 102 through the substrate 20 and the semiconductor layer 10. The bottom surface of the via 115 is adjacent the first surface 102, such that the via 115 may provide electrical contact with frontside metallization. For example, the first surface 102 may include a metal layer 104 thereon, which provides contact(s) between one or more devices in the semiconductor layer 10 and respective pads 106. In some embodiments, the metal layer 104 may be referred to as a “ Metal 1 ” (M1) metallization layer that provides a source contact to the source region of a transistor formed in the semiconductor layer 10. The first surface 102 may also include an additional interconnect layer 107 and associated electrical passivation layers 108 thereon. It will be understood that embodiments are described herein with reference to semiconductor structures including vias 115 having a metallization layer that provides a source contact to the source region of a transistor formed in the semiconductor layer 10 by way of example only, and dies, devices and related fabrication and attachment processes described herein may include other or additional vias to other transistor contacts.

In embodiments including the via 115, the metal stack 30 may be conformally formed on the second surface 103 of the substrate 20 as well as along sidewall and bottom surfaces of the via 115. The thickness of one or more layers of the metal stack 30 on the second surface 103 of the substrate 20 (portion “ 5A1 ” in FIG. 5) may differ from the thickness of one or more layers of the metal stack 30 on the sidewalls (portion “ B ” in FIG. 5) and/or bottom surface of the via 115. Barrier layer 31 may comprise a TiW layer and may serve as a electromigration and diffusion barrier. It will be understood that embodiments are described herein with reference to fabrication and attachment of embodiments of semiconductor structures including vias 115 by way of example only, and devices and related fabrication and attachment processes described herein may be applied to devices without vias 115, and are in no way limited to devices having through-substrate vias 115.

In embodiments including the via 115, the thickness of one or more layers 34, 35, and 36 of the metal stack 30 on the second surface 103 of the substrate 20 (portion “5A1” in FIG. 5) may differ from the thickness of one or more layers 34, 35, and 36 of the metal stack 30 on the sidewalls (portion “B” in FIG. 5) and/or bottom surface of the via 115.

The thickness of the metal stack 30 may also vary depending on the particular implementation. The thickness of the metal stack 30 should be thick enough to provide a continuous interface, and should account for a roughness of the a surface of a package to which the semiconductor die 100 is to be mounted. In one particular non-limiting implementation, the thickness of the metal stack 30 is in a range of about 5-15 microns, but may be thicker or thinner (e.g., 1-50 microns or 3-30 microns) depending on factors such as, for instance, the roughness of the mounting substrate, the material used for the metal stack 30, and/or a stress applied to the semiconductor die 100 during and after attachment to the surface of the package.

In some embodiments including via 115, the metal stack 30 may further include a metal interlayer 34 (such as Ni) between the barrier layer 33 and the eutectic solder layer 35, as discussed herein, which may promote enhanced interfacial stability.

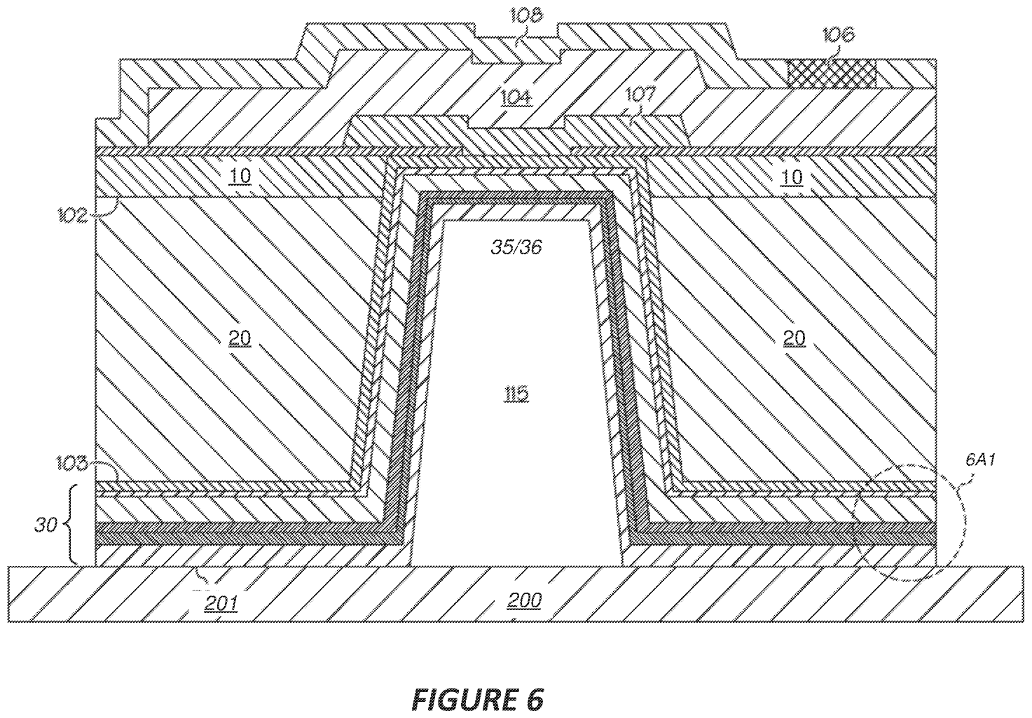

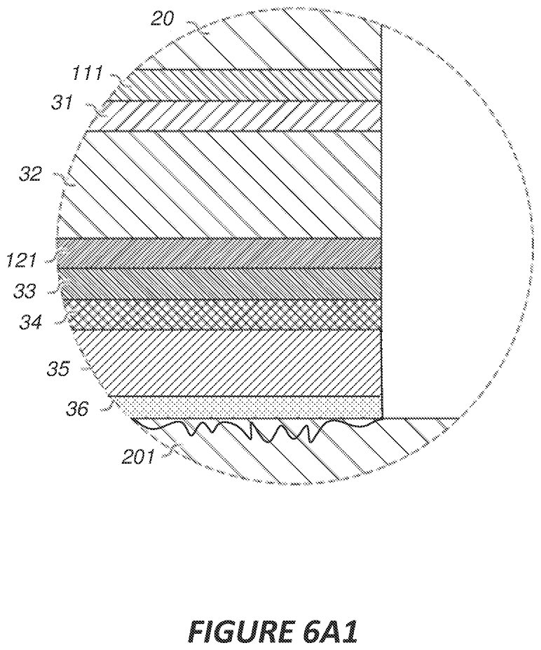

FIG. 6 is a schematic cross-sectional view of a semiconductor device including a semiconductor die 100 during die attach to a package substrate 200 in accordance with some embodiments of the present disclosure. FIG. 6A1 is an enlarged view of a portion of FIG. 6. In the example embodiment of FIG. 6, the semiconductor device is being mounted on a die attach region or flange 201 of the package substrate 200. The die attach can be either a solder-based or a gluing/sintering-based die attach operation as referenced herein.

As discussed herein, the metal stack 30 of the semiconductor die 100 includes at least one or more of the layers 31, 32, 33, 34, 35, and 36 described herein with reference to FIGS. 1-3. For example, the metal stack 30 may include a barrier layer 33, a metal interlayer 34, a eutectic solder layer 35, and a final metal layer 36. The final metal layer 36 may comprise gold (Au) on the lower surface of metal stack 30. The eutectic solder layer 35 may include gold (Au) and tin (Sn) having a ratio by weight percent of Au/Sn in a range between about 65/35 and about 80/20. The final metal layer 36 and the eutectic solder layer 35 may be configured to be compatible with any one of a eutectic solder material, a sintering material, and a glue material during attachment of the die to a package (e.g., to packaging substrate 200) as referenced herein. A sintering material may include at least one of silver (Ag), gold (Au), and copper (Cu). Metal stack 30 may further include one or more adhesion layers 111, 121. The adhesion layers 111, 121 may include one or more materials, alloys, and/or layers configured to promote adhesion with the second surface 103 of substrate 20 and with a surface of the metal layer 32, respectively. In some embodiments, the adhesion layers 111, 121 may include titanium (Ti).

The metal interlayer 34 and the final metal layer 36 may be configured to, during solder-based die attach, diffuse into the eutectic solder layer 35 during at least a partial phase transition of the eutectic solder layer 35 from a solid to a liquid state that happens during die attach that allows the attachment of the semiconductor die 100 to a surface of a package (e.g., package substrate 200) comprising at least one of Au, silver (Ag), or copper (Cu).

The metal interlayer 34 and the final metal layer 36 may be configured to stay intact during sintering/gluing-based die attach at a temperature below a eutectic melting point of the eutectic solder layer 35 that allows attachment of the semiconductor die 100 with a silver (Ag) sintering material or a glue material to a surface of a package (e.g., package substrate 200) comprising at least one of Au, silver (Ag), and copper (Cu).

The semiconductor layer 10 of the semiconductor die 100 may include a group III nitride layer or a SiC layer.

The flange or die attach region 201 may be a surface of a package substrate 200 in some embodiments. The package substrate 200 and/or the die attach region 201 may include copper (Cu) or a Cu alloy. For example, package substrate 200 and/or the die attach region 201 may be a copper-alloy, such as copper-tungsten (CuW) or CPC (a copper, copper-molybdenum, copper laminate), or a metal-matrix composite. The package substrate 200 and or the die attach region 201 may include Cu alloys with various concentrations of Cu and molybdenum (Mo). In some embodiments, one or more regions of the package substrate 200 (including the die attach region 201) may be plated with one or more metals including, but not limited to, Au, NiAu, NiPdAu, Ag, etc., for example, to reduce or prevent oxidation of larger regions of a Cu-based substrate 200.

As shown in FIG. 6, the connection between the semiconductor die 100 and flange 201 may include an unfilled via 115. The connection between the semiconductor die 100 and the package substrate 200, also referred to herein as a bond area, may thus include metal stack 30, and/or the die attach region/flange 201. The materials described herein for the metal stack 30 and the flange 201 are provided by way of example rather than limitation. In some embodiments, the materials of the metal stack 30 and the flange 201 may have similar coefficients of thermal expansion (CTEs) (e.g., about 14.4, 16, and 17, respectively, for a Au final metal layer 36, a AuSn eutectic solder layer 35, and a Cu flange 201).

In some embodiments, there may be a significant CTE mismatch between the die attach region 201 of the package substrate 200 and the semiconductor die 100 mounted thereon. The semiconductor die 100 (including the substrate 20 and the semiconductor layer 10) may be SiC-based and/or GaN-based, and may have a CTE of about 2 to 5. For example, a SiC substrate 20 and a copper-based die attach region 201 may have a CTE mismatch of about 15 or more, and the CTE of the copper-based die attach region 201 may be greater than that of the SiC substrate by a factor of about 4 or more. That is, in some embodiments, the CTE of the die attach region 201 may be at least two times, at least three times, or at least four times greater than the CTE of the semiconductor die 100 attached thereto. Such differences in CTE may contribute to concentration of stress in the bond area between the final metal layer 36 or the eutectic solder layer 35 (depending on the type of die attach operation as discussed herein) and the die attach region 201, which may result in weakening if the bond interface and/or delamination of the substrate 20 from the package substrate 200.

In some embodiments, stresses due to CTE mismatch can be alleviated by providing metal interlayer 34 between barrier layer 33 and eutectic solder layer 35 of the metal stack 30, and/or by adjusting the stoichiometry of the materials of the eutectic solder layer 35 as discussed herein. As discussed herein, the metal interlayer 34 may include one or metals (e.g., Ni, Ag, Pd, Cu), alloys, or layers. The metal interlayer 34 and the final metal layer 36 are configured to, during solder-based die attach, diffuse into the eutectic solder layer 35 during at least a partial phase transition of the eutectic solder layer 35 from a solid to a liquid state that happens during die attach that allows the attachment of the semiconductor die 100 to a surface of a package comprising at least one of Au, silver (Ag), or copper (Cu). The metal interlayer 34 and the final metal layer 36 also are configured to stay intact during gluing/sintering-based die attach at a temperature below a eutectic melting point of the eutectic solder layer that allows attachment of the semiconductor die 100 with a silver (Ag) sintering material or a glue material to a surface of a package comprising at least one of Au, silver (Ag), and copper (Cu).

For example, in embodiments where the final metal layer 36 is Au, the eutectic solder layer 35 is AuSn, and the metal interlayer 34 is Ni, during a solder-based die attach, the transition of the AuSn eutectic solder layer 35 into at least a partial liquid state may alloy with the Ni metal interlayer 34 to form a ternary NiAuSn alloy. The interaction of the metal interlayer 34 with the liquid eutectic solder layer material 35 may thus strengthen the bond area, which may be sufficient to withstand stresses due to the CTE mismatch between the SiC substrate 20 and the flange 201. An increased melting point of the ternary phase may protect the barrier layer 33 from the at least partial liquid solder which otherwise may not be able to inhibit the at least partial liquid solder breaking through the barrier layer 33. While described herein primarily with reference to ternary alloys, it will be understood that the alloy formed at or along the interface between the eutectic solder layer 35 and the metal interlayer 34 may be other (e.g., quaternary) alloys depending on the materials of the layers 34 and 35.

The semiconductor die 100 including a metallization stack 30 as described herein can be used in RF devices and/or power devices including, without limitation a high electron mobility transistor (HEMT) die and wherein the semiconductor layer comprises a gallium nitride (GaN) layer.

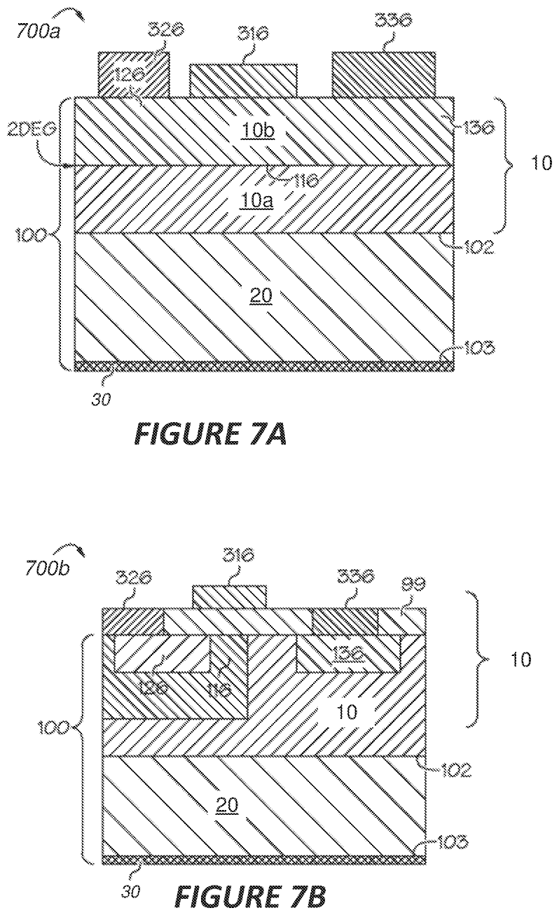

FIG. 7A is a cross-sectional view illustrating implementation of a HEMT cell structure 700a including a semiconductor die 100 in accordance with some embodiments of the present disclosure. As shown in FIG. 7A, a HEMT transistor cell 700a may include the semiconductor die 100 (including a substrate 20 and a semiconductor layer 10 on a first surface 102 of the substrate 20), and a metal stack 30 on second surface 103 of the substrate 20. The semiconductor layer 10 may include a channel layer 10a that is formed on the substrate 20, and a barrier layer 10b that is formed on a channel layer 10a. The channel layer 10a and the barrier layer 10b may include Group III-nitride based materials, with the material of the barrier layer 10b having a higher bandgap than the materials of the channel layer 10a. For example, the channel layer 10a may comprise GaN, while the barrier 10b may comprise AlGaN. While the channel layer 10a and the barrier layer 10b are illustrated as single layer structures, it will be appreciated that either or both the channel layer 10a and/or the barrier layer 10b may be implemented as multi-layer structures. It will also be appreciated that additional layers such as, for example, buffer layers, strain-balancing layers, transition layers and the like may also be include as part of the semiconductor structure provided on the substrate 20.

Due to the difference in bandgap between the materials of barrier layer 10b and the channel layer 10a and piezo-electric effects at the interface between the barrier layer 10b and the channel layer 10a, a two dimensional electron gas (2DEG) is induced in the channel layer 10a at a junction 116 between the channel layer 10a and the barrier layers 10b. The 2DEG acts as a highly conductive layer that allows conduction between the source region 126 and drain region 136 of the device beneath a source contact 326 and a drain contact 336, respectively. The source contact 326 and the drain contact 336 are formed on the barrier layer 10b. A gate contact 316 is formed on the barrier layer 10b between the drain contact 336 and the source contact 326. In some embodiments, a via (such as the via 115 described herein) may be formed to provide electrical contact between one or more of the contacts 316, 326, 336 and the metal stack 30.

FIG. 7B is a cross-sectional view illustrating implementation of a metal-oxide-semiconductor field effect transistor (MOSFET) cell, in particular, a laterally diffused metal oxide semiconductor (LDMOS) transistor sell structure 700b including a semiconductor die 100 in accordance with some embodiments of the present disclosure. The LDMOS is a 3-terminal transistor device that has a source region 126, a channel region 116, and a drain region 136 that are formed in or on a semiconductor die 100 as described herein, including metal stack 30 formed on a second surface 103 of the substrate 20). The substrate 20 may be of p-type conductivity, and the semiconductor layer 10 may provide drift layer (e.g., of n-type conductivity) thereon. The LDMOS transistor cell 700b may include doped well regions providing the source region 126 and the drain region 136. The source region 126, drain region 136, and channel region 116 of the LDMOS transistor cell 700b may be coupled to contacts for operation of the LDMOS transistor cell. For example, the channel region 116 may be electrically coupled to the gate contact 316, drain region 136 may be electrically coupled to the drain contact 336, and source region 126 may be electrically coupled to source contact 326. The channel region 116 is isolated from the gate contact 316 by an insulator layer 99 (e.g., SiO₂). Applying a positive voltage to the channel region 116 with respect to the source region 126 may provide for a current to flow between drain region 136 and the source region 126 by forming an inversion layer (e.g., a channel) between the source region 126 and the drain region 136. LDMOS FETs may operate in “enhancement mode,” meaning the drain-source current may not flow until an applied positive gate voltage enhances a channel between the drain region 136 and the source region 126. In some embodiments, a via (such as the via 115 described herein) may be formed to provide electrical contact between one or more of the contacts 316, 326, 336 and the metal stack 30.

The HEMT and LDMOS devices of FIGS. 7A and 7B are included as examples for possible configurations of a transistor unit that includes semiconductor die 100, but it will be understood that other transistor cell configurations could be utilized in die attachment of semiconductor dies as described herein without deviating from the scope of embodiments of the present disclosure. As such, the present invention is not limited to HEMT and LDMOS transistor cells.

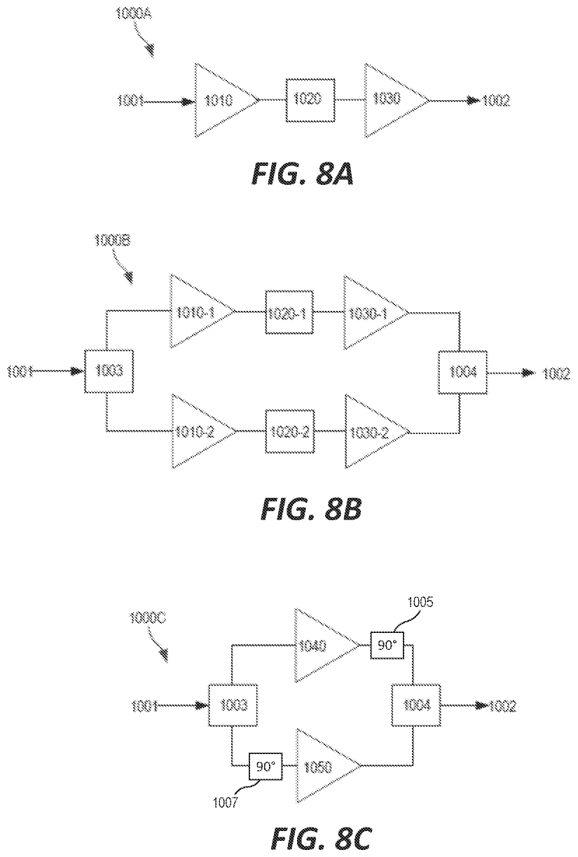

RF transistor amplifiers incorporating transistor devices described herein can be used in standalone RF transistor amplifiers and/or in multiple RF transistor amplifiers. Examples of how the RF transistor amplifiers according to some embodiments may be used in applications that include multiple amplifiers will be discussed with reference to FIGS. 8A-8C.

Referring to FIG. 8A, an RF transistor amplifier 1000A is schematically illustrated that includes a pre-amplifier 1010 and a main amplifier 1030 that are electrically connected in series. As shown in FIG. 8A, RF transistor amplifier 1000A includes an RF input 1001, the pre-amplifier 1010, an inter-stage impedance matching network 1020, the main amplifier 1030, and an RF output 1002. The inter-stage impedance matching network 1020 may include, for example, inductors and/or capacitors arranged in any appropriate configuration in order to form a circuit that improves the impedance match between the output of pre-amplifier 1010 and the input of main amplifier 1030. While not shown in FIG. 8A, RF transistor amplifier 1000A may further include an input matching network that is interposed between RF input 1001 and pre-amplifier 1010, and/or an output matching network that is interposed between the main amplifier 1030 and the RF output 1002. The RF transistor amplifiers according to embodiments may be used to implement either or both of the pre-amplifier 1010 and the main amplifier 1030.

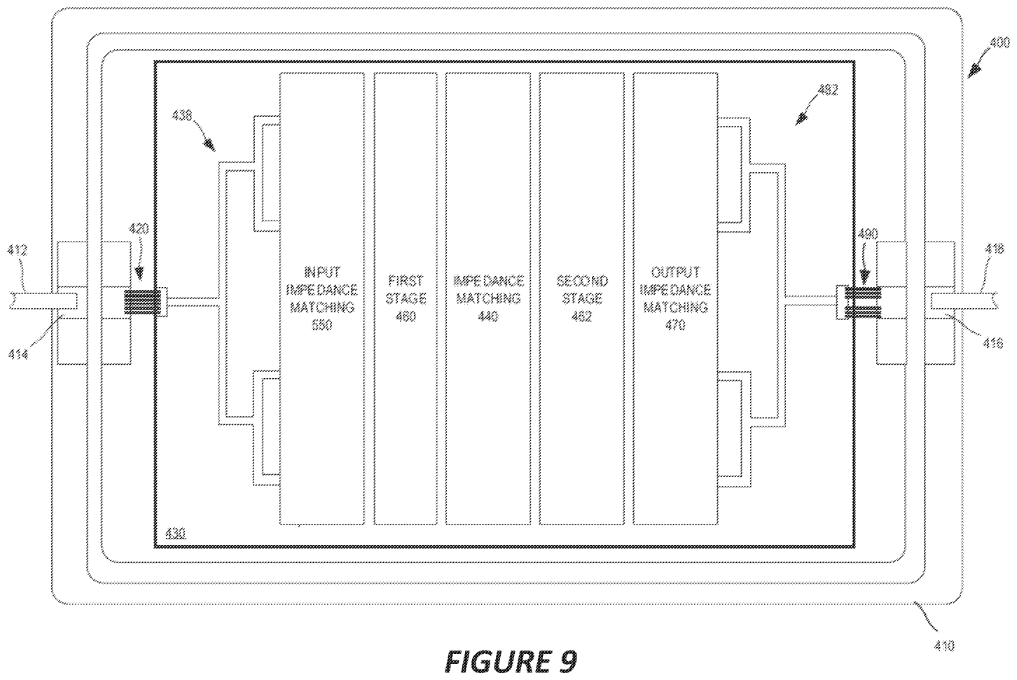

Referring to FIG. 8B, an RF transistor amplifier 1000B is schematically illustrated that includes an RF input 1001, a pair of pre-amplifiers 1010-1, 1010-2, a pair of inter-stage impedance matching networks 1020-1, 1020-2, a pair of main amplifiers 1030-1, 1030-2, and an RF output 1002. A splitter 1003 and a combiner 1004 are also provided. Pre-amplifier 1010-1 and main amplifier 1030-1 (which are electrically connected in series) are arranged electrically in parallel with pre-amplifier 1010-2 and main amplifier 1030-2 (which are electrically connected in series). As with the RF transistor amplifier 1000A of FIG. 9A, RF transistor amplifier 1000B may further include an input matching network that is interposed between RF input 1001 and pre-amplifiers 1010-1, 1010-2, and/or an output matching network that is interposed between the main amplifiers 1030-1, 1030-2 and the RF output 1002.

As shown in FIG. 8C, the RF transistor amplifiers according to some embodiments may also be used to implement Doherty amplifiers. As is known in the art, a Doherty amplifier circuit includes first and second (or more) power-combined amplifiers. The first amplifier is referred to as the “main” or “carrier” amplifier and the second amplifier is referred to as the “peaking” amplifier. The two amplifiers may be biased differently. For example, the main amplifier may comprise a Class AB or a Class B amplifier while the peaking amplifier may be a Class C amplifier in one common Doherty amplifier implementation. The Doherty amplifier may operate more efficiently than balanced amplifiers when operating at power levels that are backed off from saturation. An RF signal input to a Doherty amplifier is split (e.g., using a quadrature coupler), and the outputs of the two amplifiers are combined. The main amplifier is configured to turn on first (i.e., at lower input power levels) and hence only the main amplifier will operate at lower power levels. As the input power level is increased towards saturation, the peaking amplifier turns on and the input RF signal is split between the main and peaking amplifiers.

As shown in FIG. 8C, the Doherty RF transistor amplifier 1000C includes an RF input 1001, an input splitter 1003, a main amplifier 1040, a peaking amplifier 1050, an output combiner 1004 and an RF output 1002. The Doherty RF transistor amplifier 1000C includes a 90° transformer 1007 at the input of the peaking amplifier 1050 and a 90° transformer 1005 at the input of the main amplifier 1040, and may optionally include input matching networks and/or an output matching networks (not shown). The main amplifier 1040 and/or the peaking amplifier 1050 may be implemented using any of the above-described RF transistor amplifiers according to embodiments.

The RF transistor amplifiers according to embodiments may be formed as discrete devices, or may be formed as part of a Monolithic Microwave Integrated Circuit (MMIC). A MMIC refers to an integrated circuit that operates on radio and/or microwave frequency signals in which all of the circuitry for a particular function is integrated into a single semiconductor chip. An example MMIC device is a transistor amplifier that includes associated matching circuits, feed networks and the like that are all implemented on a common substrate. MMIC transistor amplifiers typically include a plurality of unit cell HEMT transistors that are connected in parallel.

FIG. 9 is a plan view of a MMIC RF transistor amplifier 400 according to embodiments of the present inventive concepts. As shown in FIG. 9, the MMIC RF transistor amplifier 400 includes an integrated circuit chip 430 that is contained within a package 410. The package 410 may comprise a protective housing that surrounds and protects the integrated circuit chip 430. The package 410 may be formed of, for example, a ceramic material.

The package 410 includes an input lead 412 and an output lead 418. The input lead 412 may be mounted to an input lead pad 414 by, for example, soldering. One or more input bond wires 420 may electrically connect the input lead pad 414 to an input bond pad on the integrated circuit chip 430. The integrated circuit chip 430 includes an input feed network 438, an input impedance matching network 450, a first RF transistor amplifier stage 460, an intermediate impedance matching network 440, a second RF transistor amplifier stage 462, an output impedance matching stage 470, and an output feed network 482.

The package 410 further includes an output lead 418 that is connected to an output lead pad 416 by, for example, soldering. One or more output bond wires 490 may electrically connect the output lead pad 416 to an output bond pad on the integrated circuit chip 430. The first RF transistor amplifier stage 460 and/or the second RF transistor amplifier stage 462 may be implemented using any of the RF transistor amplifiers according to embodiments of the present inventive concepts.

The RF transistor amplifiers according to embodiments of the present inventive concepts may be designed to operate in a wide variety of different frequency bands. In some embodiments, these RF transistor amplifier dies may be configured to operate in at least one of the 0.6-2.7 GHz, 3.4-4.2 GHz, 5.1-5.8 GHz, 12-18 GHz, 18-27 GHz, 27-40 GHz or 40-75 GHz frequency bands or sub-portions thereof. The techniques according to embodiments of the present inventive concepts may be particularly advantageous for RF transistor amplifiers that operate at frequencies of 10 GHz and higher.

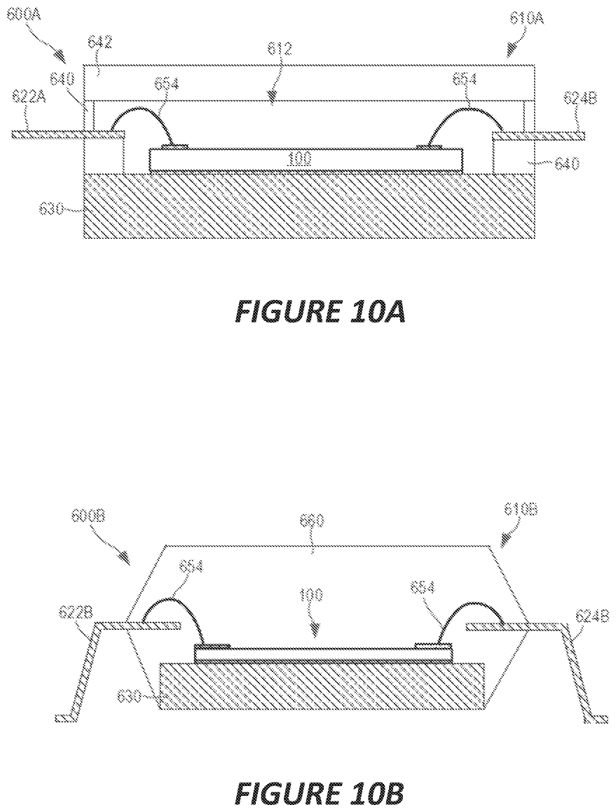

FIGS. 10A and 1013 are schematic cross-sectional views illustrating several example ways that the RF transistor amplifier dies according to embodiments of the present inventive concepts may be packaged to provide packaged RF transistor amplifiers 600A and 600B, respectively.

FIG. 10A is a schematic side view of a packaged Group III nitride-based RF transistor amplifier 600A. As shown in FIG. 10A, packaged RF transistor amplifier 600A includes the RF transistor amplifier die 100 packaged in an open cavity package 610A. The package 610A includes metal gate leads 622A, metal drain leads 624A, a metal submount 630, sidewalls 640 and a lid 642.

The submount 630 may include materials configured to assist with the thermal management of the package 600A. For example, the submount 630 may include copper and/or molybdenum. In some embodiments, the submount 630 may be composed of multiple layers and/or contain vias/interconnects. In an example embodiment, the submount 630 may be a multilayer copper/molybdenum/copper metal flange that comprises a core molybdenum layer with copper cladding layers on either major surface thereof. In some embodiments, the submount 630 may include a metal heat sink that is part of a lead frame or metal slug. The sidewalls 640 and/or lid 642 may be formed of or include an insulating material in some embodiments. For example, the sidewalls 640 and/or lid 642 may be formed of or include ceramic materials.

In some embodiments, the sidewalls 640 and/or lid 642 may be formed of, for example, Al2O3. The lid 642 may be glued to the sidewalls 640 using an epoxy glue. The sidewalls 640 may be attached to the submount 630 via, for example, braising. The gate lead 622A and the drain lead 624A may be configured to extend through the sidewalls 640, though embodiments of the present inventive concepts are not limited thereto.

The RF transistor amplifier die 100 is mounted on the upper surface of the metal submount 630 in an air cavity package 612 defined by the metal submount 630, the ceramic sidewalls 640 and the ceramic lid 642. The gate and drain terminals of RF transistor amplifier die 100 may be on the top side of the structure, while the source terminal is on the bottom side of the structure.

The gate lead 622A may be connected to the gate terminal of RF transistor amplifier die 100 by one or more bond wires 654. Similarly, the drain lead 624A may be connected to the drain terminal of RF transistor amplifier die 100 by one or more bond wires 654. The source terminal may be mounted on the metal submount 630 using, for example, a conductive die attach material (not shown). The metal submount 630 may provide the electrical connection to the source terminal 126 and may also serve as a heat dissipation structure that dissipates heat that is generated in the RF transistor amplifier die 100.

The heat is primarily generated in the upper portion of the RF transistor amplifier die 100 where relatively high current densities are generated in, for example, the channel regions of the unit cell transistors. This heat may be conducted though the source vias 146 and the semiconductor layer structure of the device to the source terminal and then to the metal submount 630.

FIG. 10B is a schematic side view of another packaged Group III nitride based RF transistor amplifier 600B. RF transistor amplifier 600B differs from RF transistor amplifier 600A in that it includes a different package 610B. The package 610B includes a metal submount 630, as well as metal gate and drain leads 622B, 624B. RF transistor amplifier 600B also includes a plastic overmold 660 that at least partially surrounds the RF transistor amplifier die 100, the leads 622B, 624B, and the metal submount 630.

Many variations of the features of the above embodiments are possible. Transistor structures with features that may be used in embodiments of the present invention are disclosed in the following commonly assigned publications, the contents of each of which are fully incorporated by reference herein in their entirety: U.S. Pat. No. 6,849,882 to Chavarkar et al. and entitled “Group-III Nitride Based High Electron Mobility Transistor (HEMT) With Barrier/Spacer Layer”; U.S. Pat. No. 7,230,284 to Parikh et al. and entitled “Insulating Gate AlGaN/GaN HEMT”; U.S. Pat. No. 7,501,669 to Parikh et al. and entitled “Wide Bandgap Transistor Devices With Field Plates”; U.S. Pat. No. 7,126,426 to Mishra et al. and entitled “Cascode Amplifier Structures Including Wide Bandgap Field Effect Transistor With Field Plates”; U.S. Pat. No. 7,550,783 to Wu et al. and entitled “Wide Bandgap HEMTs With Source Connected Field Plates”; U.S. Pat. No. 7,573,078 to Wu et al. and entitled “Wide Bandgap Transistors With Multiple Field Plates”; U.S. Pat. Pub. No. 2005/0253167 to Wu et al. and entitled “Wide Bandgap Field Effect Transistors With Source Connected Field Plates”; U.S. Pat. Pub. No. 2006/0202272 to Wu et al. and entitled “Wide Bandgap Transistors With Gate-Source Field Plates”; U.S. Pat. Pub. No. 2008/0128752 to Wu and entitled “GaN Based HEMTs With Buried Field Plates”; U.S. Pat. Pub. No. 2010/0276698 to Moore et al. and entitled “Gate Electrodes For Millimeter-Wave Operation and Methods of Fabrication; U.S. Pat. Pub. No. 2012/0049973 to Smith, Jr. et al. and entitled “High Power Gallium Nitride Field Effect Transistor Switches”; U.S. Pat. Pub. No. 2012/0194276 to Fisher and entitled “Low Noise Amplifiers Including Group III Nitride Based High Electron Mobility Transistors”; and U.S. Pat. No. 9,847,411 to Sriram et al. entitled “Recessed field plate transistor structures.”

Although embodiments of the inventive concepts have been described in considerable detail with reference to certain configurations thereof, other versions are possible. The indentations of an edge of an ohmic contact can also have many different sizes and shapes. Accordingly, the spirit and scope of the invention should not be limited to the specific embodiments described above.

What is claimed is:

1. A semiconductor die comprising:
a silicon carbide (SiC) substrate having a first surface including a semiconductor layer thereon and a second surface that is opposite the first surface; and
a metal stack having an upper surface that attaches to the second surface of the SiC substrate and a lower surface that is opposite the upper surface, the metal stack comprising a eutectic solder layer and a noble metal layer on the eutectic solder layer, wherein the noble metal layer comprises a final metal layer on the lower surface.

2. The semiconductor die of claim 1, wherein the eutectic solder layer comprises a eutectic or a near eutectic material.

3. The semiconductor die of claim 1, wherein the final metal layer comprises gold (Au) or silver (Ag).

4. The semiconductor die of claim 1, wherein the final metal layer is configured to be compatible with any one of a eutectic solder material, a sintering material, and a glue material for attachment of the semiconductor die to a package.

5. The semiconductor die of claim 1, wherein the eutectic solder layer comprises at least one of (i) gold (Au) and tin (Sn) having a respective ratio by weight percent of about 80/20, (ii) copper (Cu) and Sn having a respective ratio by weight percent of about 6/94, (iii) silver (Ag) and Sn having a respective ratio by weight percent of about 10/90, and (iv) Au and germanium (Ge) having a respective ratio by weight percent of about 20/80.

6. The semiconductor die of claim 1, wherein the eutectic solder layer comprises at least one of (i) gold (Au) and tin (Sn) having a respective ratio by weight percent of about 75/25, (ii) copper (Cu) and Sn having a respective ratio by weight percent of about 4/96, (iii) silver (Ag) and Sn having a respective ratio by weight percent of about 8/92, and (iv) Au and germanium (Ge) having a respective ratio by weight percent of about 17/83.

7. The semiconductor die of claim 1, wherein the eutectic solder layer comprises at least one of (i) gold (Au) and tin (Sn) having a respective ratio by weight percent of about 70/30, (ii) copper (Cu) and Sn having a respective ratio by weight percent of about 2/98, (iii) silver (Ag) and Sn having a respective ratio by weight percent of about 5/95, and (iv) Au and germanium (Ge) having a respective ratio by weight percent of about 14/86.

8. The semiconductor die of claim 1, wherein the eutectic solder layer comprises at least one of (i) gold (Au) and tin (Sn) having a respective ratio by weight percent of about 65/35, (ii) copper (Cu) and Sn having a respective ratio by weight percent of about 0/100, (iii) silver (Ag) and Sn having a respective ratio by weight percent of about 0/100, and (iv) Au and germanium (Ge) having a respective ratio by weight percent of about 10/90.

9. The semiconductor die of claim 1, wherein the final metal layer has a thickness of about 500 nm.

10. The semiconductor die of claim 1, wherein the final metal layer has a thickness in a range between about 50 and less than about 500 nm.

11. The semiconductor die of claim 1, wherein the final metal layer has a thickness in a range between about 500 nm and about 1000 nm.

12. The semiconductor die of claim 1, wherein the eutectic solder layer has a thickness of about 3600 nm.

13. The semiconductor die of claim 1, wherein the final metal layer is configured to diffuse into the eutectic solder layer during at least a partial phase transition of the eutectic solder layer from a solid to a liquid state that happens during a die attach that allows the attachment of the semiconductor die to a surface of a package comprising at least one of gold (Au), silver (Ag), or copper (Cu).

14. The semiconductor die of claim 13, wherein the eutectic solder layer is configured to go through the at least partial phase transition from solid to the liquid state at a temperature range of about 200° C. to about 450° C.

15. The semiconductor die of claim 13, wherein the eutectic solder layer comprises a combination of gold (Au) and tin (Sn) in a ratio by weight percent of Au/Sn in a range of about 65/35 to about 80/20, and wherein the eutectic solder layer is configured to have the phase transition to the liquid state at a temperature of about 278° C.

16. The semiconductor die of claim 1, wherein the final metal layer is configured to, stay intact during a die attach at a temperature below a eutectic melting point of the eutectic solder layer that allows attachment of the semiconductor die with at least one of a silver (Ag), gold (Au), and copper (Cu) sintering material or a glue material to a surface of a package comprising at least one of gold (Au), silver (Ag), and copper (Cu).

17. The semiconductor die of claim 16, wherein the eutectic solder layer is configured to not go through the at least partial phase transition to a liquid state at a temperature range of about 100° C. to lower than the eutectic melting point of the eutectic solder layer.

18. The semiconductor die of claim 17, wherein the final metal layer is configured to allow attachment of the semiconductor die with at least one of a Ag, a Au, and a Cu sintering material or at least one of a conductive or a non-conductive glue material at a temperature of about 200° C.

19. The semiconductor die of claim 1, wherein the semiconductor layer comprises a group Ill nitride layer.

20. The semiconductor die of claim 1, wherein the semiconductor layer comprises a SiC layer.

21. The semiconductor die of claim 1, wherein the semiconductor die comprises a high electron mobility transistor (HEMT) die and wherein the semiconductor layer comprises a gallium nitride (GaN) layer.

22. The semiconductor die of claim 1, wherein the semiconductor die comprises a metal-oxide-semiconductor field effect transistor (MOSFET) die and wherein the semiconductor layer comprises a SiC layer.

23. The semiconductor die of claim 1, wherein the semiconductor die further comprises at least one via extending through the SiC substrate from the second surface thereof toward the first surface thereof, wherein the metal stack conformally extends along the second surface of the SiC substrate and within the via along sidewall surfaces thereof such that the via is unfilled.

24. The semiconductor die of claim 1, wherein the semiconductor die comprises an RF transistor formed as part of a monolithic microwave integrated circuit (MMIC), and wherein the MMIC comprises vias connected to a circuit element of the RF transistor.

25. A semiconductor die comprising:
a silicon carbide (SiC) substrate having a first surface including a semiconductor layer thereon and a second surface that is opposite the first surface; and
a metal stack having an upper surface that attaches to the second surface of the SiC substrate and a lower surface that is opposite the upper surface, the metal stack comprising a final metal layer comprising gold (Au) on the lower surface, a eutectic solder layer on the final metal layer, a barrier layer on the eutectic solder layer, and a metal interlayer comprising nickel between the eutectic solder layer and the barrier layer.

26. The semiconductor die of claim 25, wherein the final metal layer is configured to be compatible with any one of a eutectic solder material, a sintering material, and a glue material during attachment of the die to a package.

27. The semiconductor die of claim 25, wherein the eutectic solder layer comprises gold (Au) and tin (Sn) having a ratio by weight percent of Au/Sn in a range between about 65/35 and about 80/20.

28. The semiconductor of claim 24, wherein the sintering material comprises at least one of silver (Ag), gold (Au), and copper (Cu).

29. The semiconductor die of claim 25, wherein the metal interlayer and the final metal layer are configured to diffuse into the eutectic solder layer during at least a partial phase transition of the eutectic solder layer from a solid to a liquid state that happens during die attach that allows the attachment of the semiconductor die to a surface of a package comprising at least one of Au, silver (Ag), or copper (Cu).

30. The semiconductor die of claim 25, wherein the metal interlayer and the final metal layer are configured to stay intact, during die attach at a temperature below a eutectic melting point of the eutectic solder layer that allows attachment of the semiconductor die with a silver (Ag) sintering material or a glue material to a surface of a package comprising at least one of Au, silver (Ag), and copper (Cu).

31. The semiconductor die of claim 25, wherein the semiconductor layer comprises a group Ill nitride layer.

32. The semiconductor die of claim 25, wherein the semiconductor layer comprises a SiC layer.

33. The semiconductor die of claim 25, wherein the semiconductor die comprises a high electron mobility transistor (HEMT) die and wherein the semiconductor layer comprises a gallium nitride (GaN) layer.

34. The semiconductor die of claim 25, wherein the semiconductor die comprises a metal-oxide-semiconductor field effect transistor (MOSFET) die and wherein the semiconductor layer comprises a SiC layer.

35. The semiconductor die of claim 25, wherein the semiconductor die further comprises at least one via extending through the SiC substrate from the second surface thereof toward the first surface thereof, wherein the metal stack conformally extends along the second surface of the SiC substrate and within the via along sidewall surfaces thereof such that the via is unfilled.

36. The semiconductor die of claim 25, wherein the semiconductor die comprises an RF transistor formed as part of a monolithic microwave integrated circuit (MMIC), and wherein the MMIC comprises vias connected to a circuit element of the RF transistor.
